(19) United States
(12) Patent Application Publication
(10) Pub. No.: US 2010/0007021 A1
(43) Pub. Date: Jan. 14, 2010

(54) Methods of Fabricating Semiconductor Devices Including Porous Insulating Layers

(76) Inventors: Jae-Ouk Choo, Gyeonggi-do (KR); Il-Young Yoon, Gyeonggi-do (KR); Tae-Hoon Lee, Gyeonggi-do (KR); Kyoung-Woo Lee, Gyeonggi-do (KR)

Correspondence Address: MYERS BIGEL SIBLEY & SAJOVEC, PO BOX 37428, RALEIGH, NC, 27627, US

(21) Appl. No.: 12/499,199

(22) Filed: Jul. 8, 2009

(30) Foreign Application Priority Data
Jul. 10, 2008 (KR) 2008-67102

(51) Int. Cl. H01L 23/532; H01L 21/768; H01L 23/48

(52) U.S. Cl. 257/751; 257/762; 438/637; 438/653; 257/774; 257/E21.577; 257/E21.584; 257/E23.116; 257/E23.011; 257/E23.155; 257/E23.161

(57) ABSTRACT

Semiconductor devices including a substrate and an uppermost insulating layer formed on the substrate and having pores is provided. A conductive wiring is provided in the uppermost insulating layer. Dummy vias are provided, each penetrating the uppermost insulating layer, being adjacent to the conductive wiring, and having a space therein. Related methods of fabricating semiconductor devices are also provided.

### CLAIM OF PRIORITY

This application claims priority from Korean Patent Application No. 10-2008-0067102 filed on Jul. 10, 2008 in the Korean Intellectual Property Office, the disclosure of which is incorporated herein by reference as if set forth in its entirety.

### FIELD

The present invention relates generally to semiconductor devices and, more particularly, to semiconductor devices including porous insulating layers without moisture and methods of fabricating the same.

### BACKGROUND

As semiconductor devices become more highly integrated, circuit line width is reduced, thus, the resistance of a gate pattern is also reduced. Accordingly, a conductive wiring made of a low-resistance material such as copper (Cu), may be used.

In order to form a conductive wiring, an insulating layer is etched, and, as a result, grooves, such as vias and/or trenches, are formed. Then, each of the grooves is filled with a conductive material such as Cu, and a chemical mechanical planarization (CMP) process is performed on the conductive material.

With the increasing integration density of semiconductor devices, a resistance-capacitance (RC) delay caused by back end-of-line (BEOL) metallization has become a major factor that determines the speed of semiconductor devices. In order to reduce the RC delay of semiconductor devices, a conductive wiring is insulated by using a porous insulating layer with a lower dielectric constant than that of silicon dioxide (SiO₂).

However, moisture may seep into pores of the porous insulating layer during the fabrication process of the semiconductor device, such as a groove-forming process and/or a CMP process in a damascene process. If moisture exists in the porous insulating layer, a value of an effective dielectric constant can be increased while yields are reduced. Furthermore, a time dependent dielectric breakdown, which is defined as the deterioration of characteristics of an insulating layer over time, may occur.

### SUMMARY

Some embodiments of the present invention provide semiconductor devices including a substrate and an uppermost insulating layer which is formed on the substrate and has pores. A conductive wiring is provided in the uppermost insulating layer. Dummy vias are provided, each penetrating the uppermost insulating layer, being adjacent to the conductive wiring, and having a space therein.

In further embodiments of the present invention a dummy via barrier metal layer may be provided covering sidewalls and a bottom surface of each of the dummy vias.

In still further embodiments of the present invention, a plurality of lower insulating layers may be provided between the uppermost insulating layer and the substrate. A plurality of lower conductive wirings may be provided in the lower insulating layers, respectively. The dummy vias may penetrate from the uppermost insulating layer to a lowest one of the lower insulating layers.

In some embodiments of the present invention, a plurality of capping layers are provided, each being formed between two adjacent ones of the lower insulating layers and between the uppermost insulating layer and one of the lower insulating layers which is adjacent to the uppermost insulating layer.

In further embodiments of the present invention, each of the lower conductive wirings, excluding a lowest one thereof, may be formed in a corresponding one of the lower insulating layers and the capping layer disposed under the corresponding one of the lower insulating layers, and the conductive wiring may be formed between the uppermost insulating layer and the capping layer disposed under the uppermost insulating layer.

In still further embodiments of the present invention, at least one of the conductive wiring and the lower conductive wirings may be a copper (Cu) damascene wiring layer.

In some embodiments of the present invention, a barrier metal layer may be provided surrounding the Cu damascene wiring layer.

Further embodiments of the present invention provide semiconductor devices include a substrate and a capping layer on the substrate. An insulating layer is provided on the capping layer. The insulating layer has pores. A conductive wiring is provided in the insulating layer and the capping layer. Dummy vias are provided, each penetrating at least part of the insulating layer. The capping layer and the insulating layer are repeatedly formed in an alternating fashion, each of the dummy vias is adjacent to the conductive wiring, and at least part of each of the dummy vias is filled with a material of the conductive wiring or a material of the capping layer.

In still further embodiments of the present invention, a dummy via barrier metal layer may cover sidewalls and a bottom surface of each of the dummy vias, wherein the material of the conductive wiring or the material of the capping layer may be formed on the dummy via barrier metal layer.

In some embodiments of the present invention, the dummy vias may penetrate two or more insulating layers or two or more capping layers.

In further embodiments of the present invention, an outer surface of each of the dummy vias may be surrounded by the insulating layer or the capping layer.

In still further embodiments of the present invention, at least part of each of the dummy vias may be filled with the material of the capping layer. In certain embodiments, at least part of each of the dummy vias may be filled with a material of the insulating layer.

Some embodiments of the present invention provide methods of fabricating semiconductor devices including providing a substrate; forming an insulating layer, which has pores, on the substrate; forming a conductive wiring in the insulating layer and forming dummy vias, each of which penetrates at least part of the insulating layer, is adjacent to the conductive wiring, and has a space therein; reducing moisture in the insulating layer; and forming a dummy via barrier metal layer which covers sidewalls and a bottom surface of each of the dummy vias, wherein the reducing the moisture and the forming of the dummy via barrier metal layer are performed in situ.

In further embodiments of the present invention, reducing the moisture may be performed at a temperature of from about 30 to about 400° C. and under a high-vacuum pressure of from about 0.1 to about 10 torr.

In still further embodiments of the present invention, the method further includes forming a plurality of lower insulating layers between the insulating layer and the substrate; and forming a plurality of lower conductive wirings in the lower insulating layers, respectively, wherein the insulating layer is a uppermost insulating layer, and the dummy vias penetrate from the uppermost insulating layer to a lowest one of the lower insulating layers.

In some embodiments of the present invention, the method further includes forming a plurality of capping layers, each between two adjacent ones of the lower insulating layers and between the uppermost insulating layer and one of the lower insulating layers which is adjacent to the uppermost insulating layer.

In further embodiments of the present invention, each of the lower conductive wirings, excluding a lowest one thereof, may be formed in a corresponding one of the lower insulating layers and the capping layer disposed under the corresponding one of the lower insulating layers, and the conductive wiring may be formed between the uppermost insulating layer and the capping layer disposed under the uppermost insulating layer.

In still further embodiments of the present invention, forming of the conductive wiring may include forming grooves by etching the insulating layer; forming a conductive metal material on the insulating layer and each of the grooves; and performing a chemical mechanical planarization (CMP) process on the conductive metal material to form the conductive wiring in each of the grooves.

In some embodiments of the present invention, the dummy vias may be formed at the same time as the grooves or after the conductive wiring is formed. The dummy vias may be formed at the same time as the grooves, and the forming of the conductive wiring may include filling each of the dummy vias with the conductive metal material after forming the dummy via barrier metal layer.

In further embodiments of the present invention, the method may further include forming an upper capping layer on the insulating layer after forming the dummy via barrier metal layer, wherein the dummy vias are formed after the conductive wiring is formed, and the forming of the upper capping layer comprises filling at least part of each of the dummy vias with a material of the upper capping layer.

In still further embodiments of the present invention, the method may further include forming an upper insulating layer on the upper capping layer, wherein the forming of the upper insulating layer includes filling at least part of each of the dummy vias with a material of the upper insulating layer.

In some embodiments of the present invention, the method may further include reducing moisture in the insulating layer after forming the grooves; and forming a barrier metal layer which covers sidewalls and a bottom surface of each of the grooves, wherein the reducing of the moisture and the forming of the barrier metal layer are performed in situ.

In further embodiments of the present invention, reducing the moisture may be performed at a temperature of from about 30 to about 400° C. and under a high-vacuum pressure of from about 0.1 to about 10 torr.

In still further embodiments of the present invention, the method may further include reducing moisture in the insulating layer after the CMP process; and forming the upper capping layer which covers the conductive wiring and the insulating layer, wherein the reducing the moisture and the forming of the upper capping layer are performed in situ.

In some embodiments of the present invention, the grooves and the conductive wiring may be formed by a copper (Cu) damascene process.

Further embodiments of the present invention provide methods of fabricating a semiconductor device, the method including providing a substrate; forming an insulating layer having pores on the substrate; forming grooves by etching the insulating layer; reducing moisture in the insulating layer through the grooves; forming a barrier metal layer in each of the grooves; and forming a conductive wiring in each of the grooves, wherein the reducing the moisture and the forming of the barrier metal layer are performed in situ.

In still further embodiments of the present invention, the method further may further include forming dummy vias at the same time as the grooves, wherein the moisture is reduced through the grooves and the dummy vias, and the forming of the conductive wiring comprises filling each of the dummy vias with a conductive metal material after forming a dummy via barrier metal layer.

Some embodiments of the present invention may provide methods of fabricating a semiconductor device, the method includes providing a substrate; forming an insulating layer which having pores on the substrate; forming grooves by etching the insulating layer; forming a conductive metal material on the insulating layer and each of the grooves; forming a conductive wiring in each of the grooves by performing a CMP process on the conductive metal material; reducing moisture in the insulating layer; and forming an upper capping layer on the insulating layer and the conductive wiring, wherein the reducing of the moisture and the forming of the upper capping layer are performed in situ.

In further embodiments of the present invention, the method may further include forming dummy vias after forming the conductive wiring; and forming a dummy via barrier metal layer on sidewalls and a bottom surface of each of the dummy vias, wherein the forming of the upper capping layer is performed after the forming of the dummy via barrier metal layer and comprises filling at least part of each of the dummy vias with a material of the upper capping layer.

IN still further embodiments of the present invention, the method may further include forming an upper insulating layer on the upper capping layer, wherein the forming of the upper insulating layer comprises filling at least part of each of the dummy vias with a material of the upper insulating layer.

### BRIEF DESCRIPTION OF THE DRAWINGS

FIG. 1 is a cross-section illustrating a semiconductor device according to some embodiments of the present invention.

FIG. 2 is a plan view illustrating semiconductor devices according to some embodiments of the present invention.

FIGS. 3A and 3B are cross sections illustrating semiconductor devices according to some embodiments of the present invention.

FIGS. 4 through 11 are cross sections illustrating processing steps in the fabrication of semiconductor devices according to some embodiments of the present invention.

FIGS. 12 through 16 are cross sections illustrating processing steps in the fabrication of semiconductor devices according to some embodiments of the present invention.

FIGS. 17 and 18 are cross sections illustrating processing steps in the fabrication of semiconductor devices according to some embodiments of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

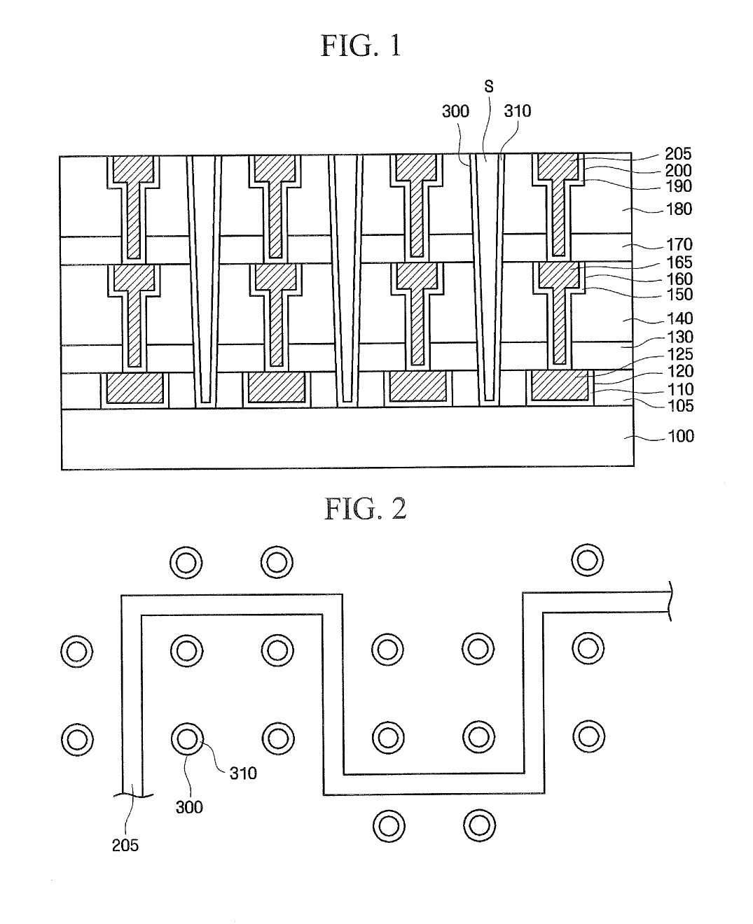

Referring first to FIG. 1, a cross section illustrating semiconductor devices according to some embodiments of the present invention will be discussed. As illustrated in FIG. 1, semiconductor devices according to some embodiments of the present invention include a plurality of insulating layers 105, 140, and 180 on a substrate 100, a plurality of capping layers 130 and 170 between the insulating layers 105, 140, and 180, a plurality of conductive wirings 125, 165, and 205 in the insulating layers 105, 140, and 180 and the capping layers 130 and 170, and a plurality of dummy vias 300, each of which provided adjacent to the conductive wirings 125, 165, and 205.

In some embodiments, the substrate 100 may be a rigid substrate or a flexible plastic substrate without departing from the scope of the present invention. In embodiments including a rigid substrate, the rigid substrate may include, for example, a substrate which is made of one or more semiconductor materials selected from Si, Ge, SiGe, GaP, GaAs, SiC, SiGeC, InAs and InP, a silicon-on-insulator (SOI) substrate, a quartz substrate, and a display glass substrate. In embodiments including a flexible substrate, the flexible plastic substrate may include, for example, polyimide, polyethylene terephthalate (PET), polyethylene naphthalate (PEN), polymethyl methacrylate (PMMA), polycarbonate (PC), polyether sulfone (PES), or polyester.

Switching devices, such as transistors, are disposed on the substrate 100. The substrate 100 includes source and drain regions (not shown). An insulating layer (not shown), which covers the switching devices such as transistors, is formed on the substrate 100, and a conductive wiring, which electrically connects the transistors and the source and drain regions to an external power source, is formed on the insulating layer.

The lowest conductive wiring 125 and the lowest insulating layer 105 according to some embodiments of the present invention are disposed on the transistors. Throughout the specification, the terms “lower” and “upper” are used as relative terms.

The lowest insulating layer 105 is formed on the substrate 100. The lowest insulating layer 105 is a low-k insulating layer and includes pores. As used herein, the term “low-k” refers to a dielectric constant lower than a dielectric constant of silicon dioxide (SiO₂), that is, lower than approximately 4. The low-k insulating layer may be made of an organic polymer or an inorganic material.

A low-k organic polymer may be, for example, a polyarylether resin, cyclic fluorine resin, a siloxane copolymer, fluorinated polyallylether resin, polypentafluorostyrene, polytetrafluorostyrene resin, fluorinated polyimide resin, polynaphthalene fluoride, or polycide resin.

The inorganic material may be, for example, undoped silicate glass (USG), tetraethylorthosilicate (TEOS), fluorine-doped silicate glass (FSG), organosilicate glass (OSG) (SiOC(SiOC:H)), hydrogensilsesquioxane (HSQ), or methyl silsesquioxane (MSQ).

The lowest insulating layer 105 may include pores. The pores may be formed in the lowest insulating layer 105 when porogen coexisting with an insulating material is selectively dissolved by heat or plasma. Examples of the porogen, which creates pores, may include, for example, tetradecane (C₁₄H₃₀) and acrylic polymer nano particles.

A plurality of lowest grooves 120 may be formed in the lowest insulating layer 105. Each of the lowest grooves 120 may be a via or a trench that is to be filled with a conductive material, such as copper (Cu).

Furthermore, a lowest barrier metal layer 110 may be formed on sidewalls and a bottom surface of each of the lowest grooves 120. The lowest barrier metal layer 110 may reduce the likelihood or even prevent a conductive material, for example, Cu, which is formed in each of the lowest grooves 120, from coming out of each of the lowest grooves 120 and helps the lowest conductive wiring 125 to be more securely attached to the lowest insulating layer 105 with a low dielectric constant. The lowest barrier metal layer 110 may be made of at least one of TiW, Ti, TiN, WN, Ta, TaW, and TaN.

The lowest conductive wiring 125 is formed on the lowest barrier metal layer 110 in each of the lowest grooves 120. The lowest conductive wiring 125 may be made of any one of Al, Al-alloy, Cu, Au, Ag, W, and Mo. For example, the lowest conductive wiring 125 may be a Cu damascene wiring layer. In this case, the lowest barrier metal layer 110 may surround the Cu damascene wiring layer to prevent Cu from coming out of each of the lowest grooves 120.

The capping layer 130 may be formed on the lowest insulating layer 105 and the lowest conductive wiring 125. The capping layer 130 may prevent the leakage of a metal material of the lowest conductive wiring 125 or the conductive wiring 165. In addition, the capping layer 130 may function as an etch-stop layer. The capping layer 130 seals pores formed in the insulating layer 140 to hinder the elimination of moisture from the insulating layer 140. The capping layer 130 may be made of SiN, SiCN, or the like.

The insulating layer 140 is formed on the capping layer 130. Like the lowest insulating layer 105, the insulating layer 140 may be made of a low-k material and include pores.

A plurality of grooves 160 may be formed in the insulating layer 140. Alternatively, the grooves 160 may be formed in both of the insulation layer 140 and the capping layer 130. Each of the grooves 160 may consist of a via and a trench. In this case, a metal material of a conductive wiring formed in the trench may function as a lower conductive wiring 165, and a metal material of a conductive wiring formed in the via may electrically connect the lower conductive wiring 165 to the lowest conductive wiring 125.

A barrier metal layer 150 may be formed on sidewalls and a bottom surface of each of the grooves 160. The function and material of the barrier metal layer 150 are substantially identical to those of the lowest barrier metal layer 110.

The conductive wiring 165 may be formed on the barrier metal layer 150 in each of the grooves 160. The conductive wiring 165 may be made of substantially the same material as the lowest conductive wiring 125.

The capping layer 130 and the insulating layer 140 may be repeatedly formed in an alternating fashion. That is, after the lowest insulating layer 105 is formed on the substrate 100, a plurality of pairs of the capping layer 130 and the insulating layer 140 may be formed on the lowest insulating layer 105.

Specifically, the capping layer 130 may be formed between every two adjacent insulating layers 140, and the uppermost capping layer 170 may be formed between the uppermost insulating layer 180 and one of the insulating layers 140 which is adjacent to the uppermost insulation layer 180.

A capping layer which is located uppermost, that is, upper than the capping layers 130 and an insulating layer 140 which is located uppermost are referred to as the uppermost capping layer 170 and the uppermost insulating layer 180, respectively. Accordingly, the capping layers 130 and the insulating layers 140 are referred to as lower capping layers and lower insulating layers relative to the uppermost capping layer 170 and the uppermost insulating layer 180, respectively.

Although semiconductor devices according to some embodiments of the present invention are discussed based on the assumption that it includes only one insulating layer 140 and one capping layer 130, embodiments of the present invention are not limited to this configuration. For example, semiconductor devices in accordance with some embodiments of the present invention may include a plurality of insulating layers 140 and a plurality of capping layers 130 without departing from the scope of the present invention.

The conductive wiring 165 may be formed in the insulating layer 140. Alternatively, the conductive wiring 165 may be formed in both of the capping layer 130 and the insulating layer 140. The conductive wiring 165 is also referred to as a lower conductive wiring relative to a highest conductive wiring. Specifically, the lower conductive wiring 165, excluding the lowest conductive wiring 125, is formed in the lower insulating layer 140 and the lower capping layer 130 which is disposed under the lower insulating layer 140, and the conductive wiring 205 is formed in the uppermost insulating layer 180 and the uppermost capping layer 170 which is disposed under the uppermost insulating layer 180.

The uppermost capping layer 170 may be formed on the insulating layer 140 and the conductive wiring 165. The uppermost capping layer 170 is made of substantially the same material as the capping layer 130 and performs substantially the same function as the capping layer 13.

The uppermost insulating layer 180 is formed on the uppermost capping layer 170. The uppermost insulating layer 180 may be made of the same material as the insulating layer 140 and perform the same function as the insulating layer 140.

A plurality of uppermost grooves 200 are formed in the uppermost insulating layer 180. Alternatively, the uppermost grooves 200 may be formed in both of the uppermost insulating layer 180 and the uppermost capping layer 170. A uppermost barrier metal layer 190 is formed on sidewalls and a bottom surface of each of the uppermost grooves 200.

The conductive wiring 205 is formed on the uppermost barrier metal layer 190 in each of the uppermost grooves 200. The conductive wiring 205 formed in each of the uppermost grooves 200 may be the uppermost one of the conductive wirings formed on the substrate 100. In these embodiments, external power may be applied to the semiconductor device via the conductive wiring 205. However, when the conductive wiring 205 is not the uppermost one, a separate uppermost conductive wiring may further be formed on the conductive wiring 205, and external power may be applied to the semiconductor device via the separate uppermost conductive wiring.

At least one of the conductive wirings 205 and 165 may be a copper damascene wiring layer. In these embodiments, at least one of the barrier metal layers 150 and 190 may surround the copper damascene wiring layer.

The dummy vias 300 according to some embodiments of the present invention will now be discussed with reference to FIGS. 1 and 2. FIG. 2 is a plan view of the semiconductor device according to some embodiments of the present invention.

Each of the dummy vias 300 may penetrate at least part of the uppermost insulating layer 180. Furthermore, each of the dummy vias 300 may be formed adjacent to the conductive wiring 205. Sidewalls and a bottom surface of each of the dummy vias 300 may be covered with a dummy via barrier metal layer 310. Furthermore, each of the dummy vias 300 according to some embodiments of the present invention may have a space S therein.

The dummy vias 300 may reduce or possibly eliminate moisture from the uppermost insulating layer 180. Since the dummy vias 300 eliminate moisture from the uppermost insulating layer 180, the time dependent dielectric breakdown (TDDB) of the uppermost insulating layer 180 can be reduced. The dummy vias 300 may be disposed around the conductive wiring 205. As the number of the dummy vias 300 formed around the conductive wiring 205 increases, the resistance of the conductive wiring 205 is reduced, and electrical characteristics thereof are enhanced.

Each of the dummy vias 300 according to some embodiments of the present invention may penetrate not only the uppermost insulating layer 180 but also at least one insulating layer 140. Each of the dummy vias 300 may also penetrate the lowest insulating layer 105. The number of insulating layers, which are to be penetrated by the dummy vias 300, may be determined based on processing convenience and yields.

When the dummy vias 300 penetrate all of the insulating layers 105, 140, and 180, moisture can be more easily eliminated from the insulating layers 105, 140, and 180, and the resistance of the conductive wirings 125, 165, and 205 around the dummy vias 300 can be reduced, which, in turn, improves electrical characteristics of the conductive wirings 125, 165 and 205. Since the resistance of the conductive wirings 125, 165, and 205 is reduced as the number of the dummy vias 300 around the conductive wirings 125, 165, and 205 increases, the dummy vias 300 may be disposed along both sides of a wiring pattern of the conductive wiring layers 125, 165, and 205.

The dummy via barrier layer 310, which is formed on the sidewalls and the bottom surface of each of the dummy vias 300, may reduce the likelihood and possibly prevent moisture from seeping into the insulating layers 105, 140, and 180 again after being eliminated from the insulating layers 105, 140, and 180.

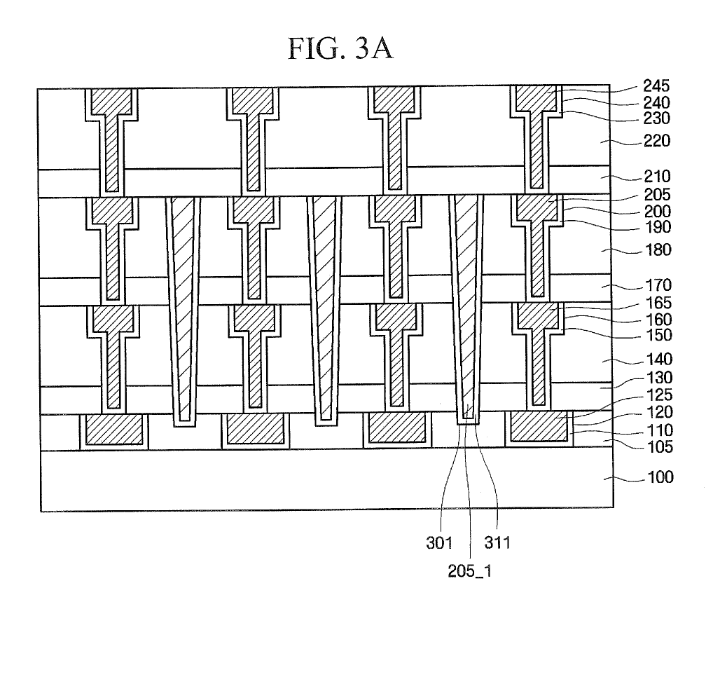

Referring now to FIGS. 3A and 3B, semiconductor devices according to some embodiments of the present invention will be discussed. Embodiments of the present invention illustrated in FIGS. 3A and 3B are substantially similar to those discussed above with respect to FIGS. 1 and 2. Accordingly, many of the details will not be repeated herein in the interest of brevity. In the embodiments of the present invention discussed with respect to FIGS. 3A and 3B, at least part of each dummy via is filled with a material of a conductive wiring or a material of a capping layer.

Referring to FIG. 3A, a capping layer 130 and an insulating layer 140 are formed on a lowest insulating layer 105. In addition, another capping layer 170 and another insulating layer 180 may be formed on the insulating layer 140. A conductive wiring 165 may be formed in the capping layer 130 and the insulating layer 140, and a conductive wiring 205 may be formed in the capping layer 170 and the insulating layer 180. When necessary, more than one conductive wiring 165 may be formed in the capping layer 130 and the insulating layer 140, and more than one conductive wiring 205 may be formed in the capping layer 170 and the insulating layer 180.

A uppermost capping layer 210 and a uppermost insulating layer 220 are formed on the insulating layer 180. A plurality of uppermost grooves 240 are formed in the uppermost insulating layer 220. In addition, inner sidewalls and a bottom surface of each of the uppermost grooves 240 are covered with a barrier metal layer 230. A conductive wiring 245 may be formed in each of the uppermost grooves 240. The conductive wiring 245 may be a copper damascene wiring layer. The barrier metal layer 230 may surround the copper damascene wiring layer.

Each of dummy vias 301 according to some embodiments of the present invention may be filled with a material 205_1 of the conductive wiring 205. A dummy via barrier metal layer 311 may cover sidewalls and a bottom surface of each of the dummy vias 301. Specifically, the material 205_1 of the conductive wiring 205 may be formed on the dummy via barrier metal layer 311.

Each of the dummy vias 301 according to some embodiments of the present invention may penetrate one insulating layer 180. Alternatively, each of the dummy vias 301 may penetrate two or more insulating layers 140 and 180 or two or more capping layers 130 and 170.

An outer surface of each of the dummy vias 301 may be surrounded by the insulating layers 105, 140, and 180 or the capping layers 130 and 170. That is, a lower part of each of the dummy vias 301 is covered with the insulating layer 105, and an outer side surface of each of the dummy vias 301 is surrounded by at least one of the insulating layers 105, 140, and 180 or the capping layers 130 and 170. In addition, an upper part of each of the dummy vias 301 is surrounded by the insulating layers 140 and 180 or the capping layers 130 and 170.

The dummy vias 301 according to some embodiments of the present invention can reduce the likelihood or possibly eliminate moisture from the intermediate insulating layers 140 and 180. When the dummy vias 301 are formed from the uppermost insulating layer 220, it may be difficult to connect the dummy vias 301 to the insulating layer 140 which is disposed under the uppermost insulating layer 220. However, according to the present embodiment, the dummy vias 301 can also be easily formed in the insulating layer 140. In the present embodiment, each of the dummy vias 301 may be filled with a material at the same time as when the conductive wirings 165 and 205 are formed.

Referring now to FIG. 3B, at least part of each of the dummy vias 301 may be filled with materials 210_1 of both of the capping layers 170 and 210. Alternatively, each of the dummy vias 301 may be filled with the material 210_1 of the capping layer 210.

Each of the dummy vias 301 may be filled with the material 210_1 of the capping layer 210 and a material 220_1 of the insulating layer 220. That is, the lower part of each of the dummy vias 301 may be filled with the material 210_1 of the capping layer 210, and the upper part of each of the dummy vias 301 may be filled with the material 220_1 of the insulating layer 220.

As discussed above, each of the dummy vias 301 according to some embodiments of the present invention may be filled with the material 210_1 of the capping layer 210, which is disposed thereon, or with the material 210_1 of the capping layer 210 and the material 220_1 of the insulating layer 220. Alternatively, each of the dummy vias 301 according to the present embodiment may be filled with the material 205_1 of the conductive wiring 205 which is disposed at a position corresponding to the upper part of each of the dummy vias 301. That is, the dummy vias 301 are formed in the intermediate, not final, stage of the fabrication process of the semiconductor device according to the present embodiment, and then subsequent processes are performed. Thus, the dummy vias 301 are formed in the intermediate insulating layers 140 and 180. As a result, moisture can be reduced or possibly eliminated from the intermediate insulating layers 140 and 180.

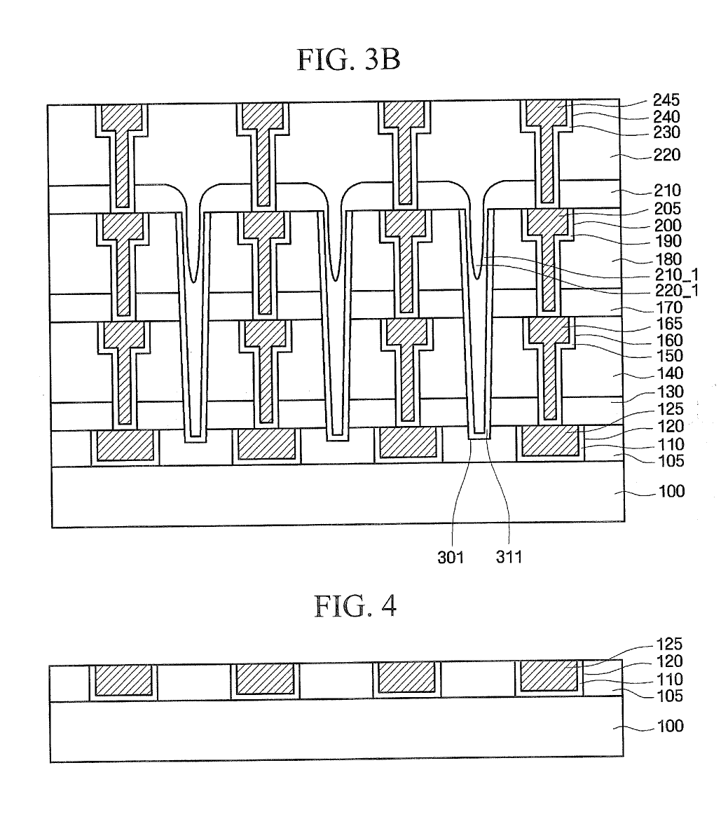

Processing steps in the fabrication of semiconductor devices in accordance with some embodiments of the present invention will now be discussed with respect to FIGS. 4 through 11. FIGS. 4 through 11 are cross sections illustrating processing steps in the fabrication of semiconductor devices in accordance with some embodiments of the present invention.

Referring now to FIG. 4, a substrate 100 is provided. The substrate 100 may be made of the material described above in relation to embodiments discussed above. A lowest insulating layer 105 is formed on the substrate 100. The lowest insulating layer 105 may be formed by plasma enhanced chemical vapor deposition (PECVD), high density plasma CVD (HDP-CVD), atmospheric pressure CVD (APCVD), or spin-coating. When the lowest insulating layer 105 is formed or when the lowest insulating layer 105 is heat-treated or plasma-treated after being formed, pores may be formed in the lowest insulating layer 105 due to porogen.

After the lowest insulating layer 105 is formed, a plurality of lowest grooves 120 may be formed in the lowest insulating layer 105. A lowest barrier metal layer 110 is formed on inner sidewalls and a bottom surface of each of the lowest grooves 120. In the present embodiment, each of the lowest grooves 120 is shaped like a trench. However, the shape of each of the lowest grooves 120 is not limited to that of a trench. That is, each of the lowest grooves 120 may be shaped like a via or a combination of a trench and a via.

The lowest barrier metal layer 110 is formed in each of the lowest grooves 120. Then, a lowest conductive wiring 125 may be formed on the lowest barrier metal layer 110 in each of the lowest grooves 120. The lowest conductive wiring 125 may be made of at least one of Al, Al-alloy, Cu, Au, Ag, W, and Mo. The lowest conductive wiring 125 may be formed by using a sputtering method followed by a reflow method. Alternatively, the lowest conductive wiring 125 may be formed by CVD or electroplating.

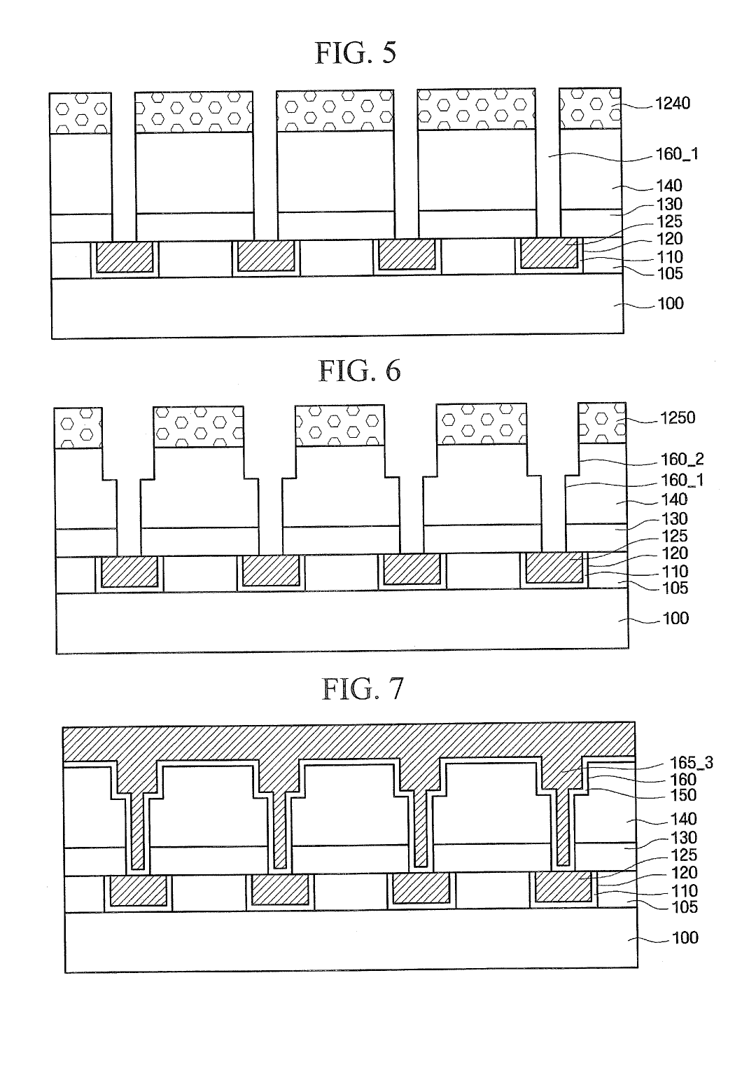

Referring now to FIG. 5, a capping layer 130 may be formed on the lowest insulating layer 105. The capping layer 130 may be formed by PECVD, HDP-CVD, APCVD, or spin-coating.

An insulating layer 140 is formed on the capping layer 130. The insulating layer 140 may be formed in the same way as the lowest insulating layer 105.

A first photoresist pattern 1240 is formed on the insulating layer 140. Then, the insulating layer 140 and the capping layer 130 are etched by using the first photoresist pattern 1240 as an etch mask to form vias 160_1. After the vias 160_1 are formed, the first photoresist pattern 1240 is removed by using a stripper.

Referring now to FIG. 6, a second photoresist pattern 1250 is formed on the insulating layer 140. Then, the insulating layer 140 is etched by using the second photoresist pattern 1250 as an etch mask to form trenches 160_2 on the vias 160_1, respectively.

While the vias 160_1 and the trenches 160_2 are formed, moisture may seep into the insulating layer 140 and remain in the pores of the insulating layer 140.

Referring now to FIGS. 6 and 7, a barrier metal layer 150 is formed on the insulating layer 140 and each of grooves 160 which consist of the vias 160_1 and the trenches 160_2, respectively. The barrier metal layer 150 may be formed in the same way as the lowest barrier metal layer 120.

A conductive metal material 165_3 is formed on the barrier metal layer 150 in each of the grooves 160. The conductive metal material 165_3 may be at least one of Al, Al alloy, Cu, Au, Ag, W, and Mo. The conductive metal material 165_3 may be formed by using a sputtering method followed by a reflow method. Alternatively, the conductive metal material 165_3 may be formed by CVD or electroplating.

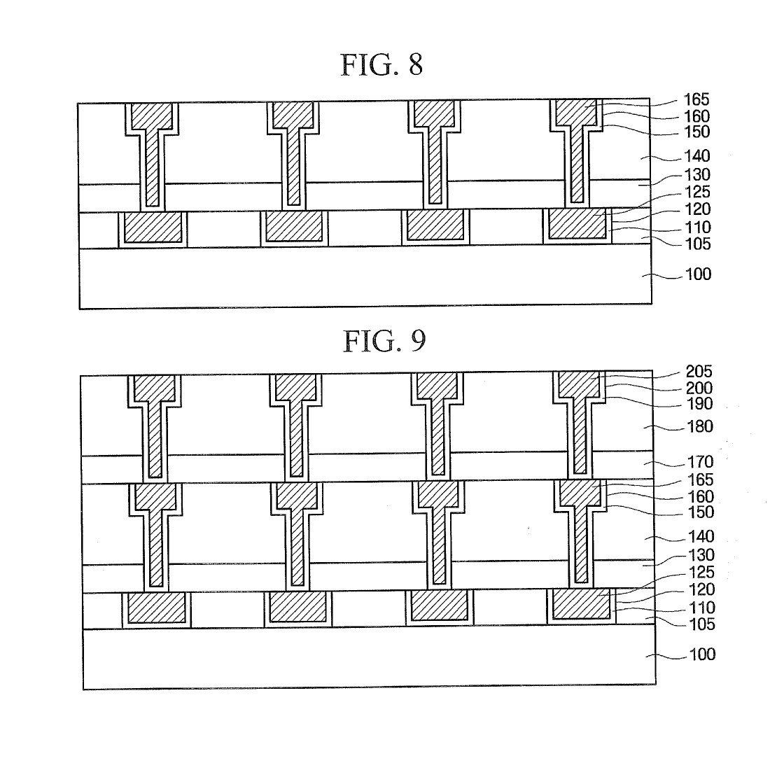

Referring now to FIGS. 7 and 8, a chemical mechanical planarization (CMP) process is performed on the conductive metal material 165_3 and the barrier metal layer 150 to form a conductive wiring 165. During the CMP process, moisture may seep into the insulating layer 180 and remain in pores of the insulating layer 180.

The processes described above with reference to FIGS. 5 through 8 may be repeated a plurality of times to repeatedly form the capping layer 130, the insulating layer 140, and the conductive wiring 165 which is formed in the capping layer 130 and the insulating layer 140. In these embodiments, the capping layer 130 may be interposed between every two adjacent ones of the insulating layers 140.

In embodiments of the present invention where the grooves 160, which penetrate the insulating layer 140 and the capping layer 130, and the conductive wiring 165 are formed by using a via-first method of a dual-damascene process, has been described above. However, the method of forming the grooves 160 and the conductive wiring 165 is not limited to the via-first method. That is, a trench-first method of the dual-damascene process and a single damascene process may also be used.

Referring now to FIG. 9, an uppermost capping layer 170 and an uppermost insulating layer 180 are formed on the insulating layer 140, and a plurality of grooves 200 are formed in the uppermost capping layer 170 and the uppermost insulating layer 180 by using the method described above with reference to FIGS. 5 through 8. A uppermost barrier metal layer 190 and a conductive wiring 205 are formed in each of the grooves 200.

While each of the grooves 200 and the conductive wiring 205 are formed, moisture may seep into the insulating layer 180 and remain in pores of the insulating layer 180.

When the conductive layer 205 is not a uppermost wiring layer, the uppermost wiring layer may further be formed on the uppermost insulating layer 180.

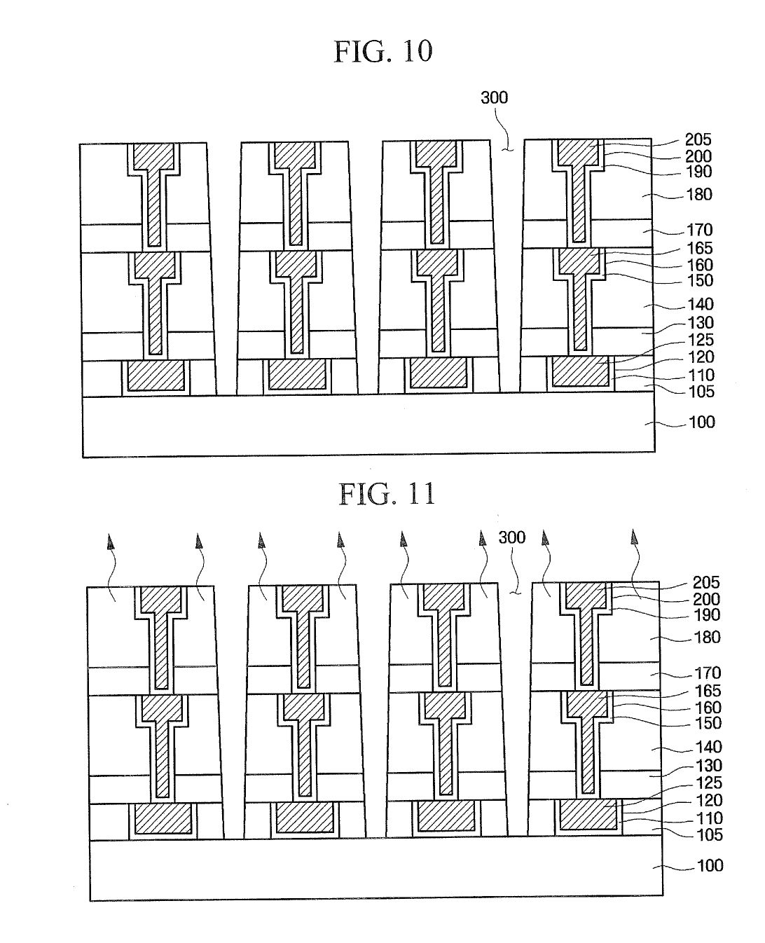

Referring now to FIG. 10, dummy vias 300 are formed in the uppermost insulating layer 180. Each of the dummy vias 300 penetrates at least part of the uppermost insulating layer 180. That is, each of the dummy vias 300 is formed by etching at least part of the uppermost insulating layer 180. Each of the dummy vias 300 may penetrate from the top of the uppermost insulating layer 180 to the lowest insulating layer 105.

In embodiments of the present invention where the dummy vias 300 are formed after the conductive wiring 205 is formed and just before a packaging process has been described above. However, the dummy vias 300 may also be formed at the same time as the grooves 160 or 200 in FIGS. 5 and 6 or 9. In these embodiments, each of the dummy vias 300 may be filled with a conductive metal material (i.e., the material 205_1 of the conductive wiring 205 in FIG. 3A) in a subsequent process.

Alternatively, the dummy vias 300 may be formed after the CMP process is performed to form the conductive wiring 165 and before the uppermost capping layer 170 is formed. In this case, at least part of each of the dummy vias 300 may be filled with a material of a capping layer (i.e., the material 210_1 of the capping layer 210 in FIG. 3B). That is, each of the dummy vias 300 is filled with the material of the capping layer at the same time as when the uppermost capping layer 170 is formed. Furthermore, at least part of each of the dummy vias 300 may be filled with a material of an insulating layer (i.e., the material 220_1 of the insulating layer 220 in FIG. 3B). In this case, each of the dummy vias 300 may be filled with the material of the capping layer and the material of the insulating layer.

The sidewalls or bottom surface of each of the dummy vias 300 formed as described above are connected to the pores of the insulating layers 105, 140, and 180. Therefore, moisture can be reduced in or possibly eliminated from the pores. To better eliminate moisture, the insulating layers 105, 140, and 180 are heat-treated and vacuum-treated as follows.

Referring now to FIG. 11, the insulating layers 105, 140 and 180 and the capping layers 130 and 170 are heat-treated to reduce moisture in or eliminate moisture from the insulating layers 105, 140 and 180 and/or the capping layers 130 and 170. While the insulating layers 105, 140 and 180 and the capping layers 130 and 170 are heat-treated, they may also be vacuum-treated. Through the vacuum treatment, moisture can be sucked up and thus eliminated from the insulating layers 105, 140, and 180 and the capping layers 130 and 170.

The insulating layers 105, 140 and 180 and the capping layers 130 and 170 may be heat-treated at a temperature of from about 30 to about 400° C. When the temperature is lower than 30° C., transistors disposed under the lowest insulating layer 105 can be damaged.

Furthermore, the insulating layers 105, 140 and 180 and the capping layers 130 and 170 may be vacuum-treated under a high-vacuum pressure of from about 0.1 to about 10 torr. When the pressure is lower than 0.1 torr, the effect of the vacuum treatment may be insignificant. When the pressure is greater than 10 torr, the insulating layers 105, 140 and 180 and/or the capping layers 130 and 170 can be damaged.

Referring to FIG. 1, a dummy via barrier metal layer 310 is formed to cover sidewalls and a bottom surface of each of the dummy vias 300. In these embodiments, the moisture elimination process of FIG. 11 and the process of forming the dummy via barrier metal layer 310 may be performed in situ. That is, since the dummy via barrier layer 310 is formed in a vacuum chamber immediately after moisture is eliminated through the heat treatment and the vacuum treatment, there is no time for moisture to seep into the insulating layers 105, 140 and 180 and/or the capping layers 130 and 170. In addition, the dummy via barrier metal layer 310 hinders moisture from seeping into the insulating layers 105, 140 and 180 and/or the capping layers 130 and 170.

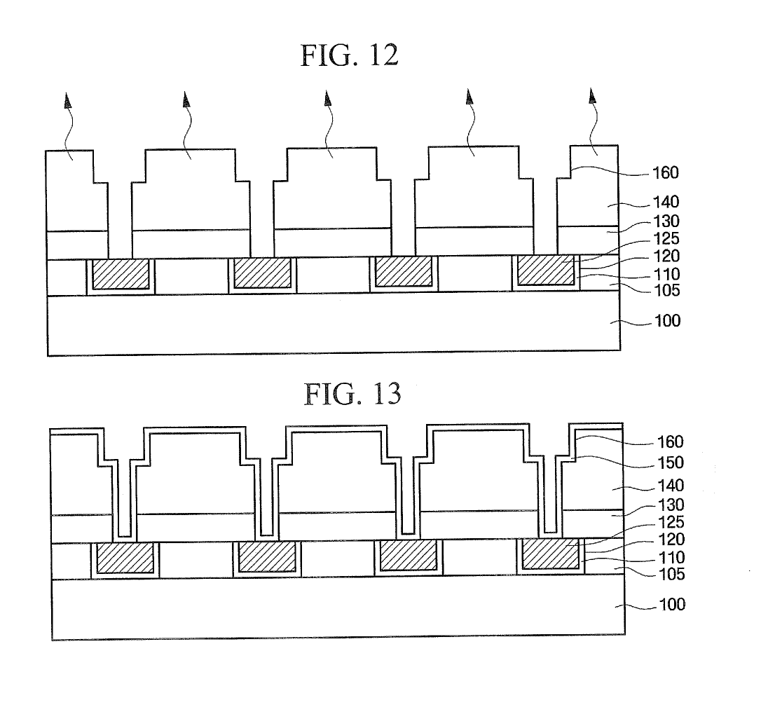

Hereinafter, a method of fabricating a semiconductor device according to some embodiments of the present invention will be discussed with respect to FIGS. 1, 4 through 11, and 12 through 16. FIGS. 12 through 16 are cross sections illustrating processing steps in the fabrication of semiconductor devices in accordance with some embodiments of the present invention.

Through the processes described above with reference to FIGS. 4 through 6, a plurality of grooves 160 are formed by etching an insulating layer 140 having pores. The grooves 160 may be formed in a capping layer 130 and the insulating layer 140.

Referring to FIG. 12, moisture is reduced or possibly eliminated from the pores of the insulating layer 140 through the grooves 160. The insulating layer 140 is heat-treated and vacuum-treated to eliminate moisture from the pores. Specifically, moisture may be eliminated from the pores of the insulating layer 140 at a temperature of from about 30 to about 400° C. and under a high-vacuum pressure of from about 0.1 to about 10 torr. When moisture is eliminated within the above temperature and pressure range, it can be eliminated without deteriorating characteristics of the insulating layer 140 or transistors under a lowest insulating layer 105.

Referring now to FIG. 13, a barrier metal layer 150 is formed on the insulating layer 140 and inner sidewalls and a bottom surface of each of the grooves 160. The barrier metal layer 150 may reduce or possibly prevent moisture from seeping into the insulating layer 140 again.

The moisture reduction process of FIG. 12 and the process of forming the barrier metal layer 150 of FIG. 13 may be performed in situ. Since the barrier metal layer 150 is formed immediately after the reduction of moisture, the possibility that moisture will seep into the insulating layer 140 again is reduced.

Each of the grooves 160 is filled with a conductive metal material 165_3 by using the method described above with reference to FIGS. 7 and 8. The CMP process is performed on each of the grooves 160 to form a conductive wiring 165.

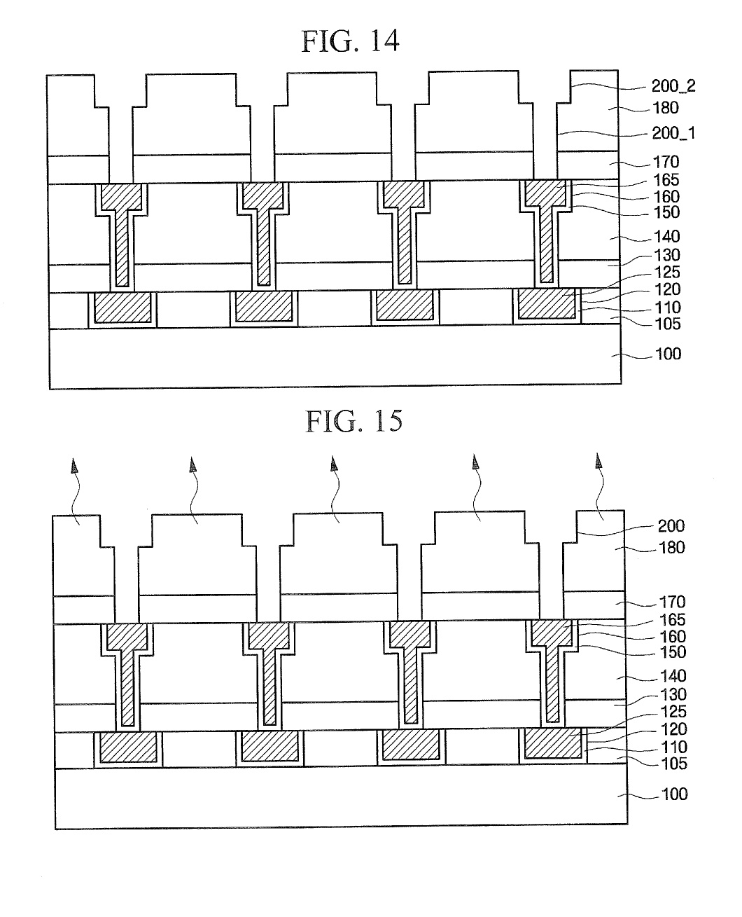

Referring now to FIG. 14, an upper capping layer 170 and an upper insulating layer 180 are formed on the insulating layer 140. Then, the upper capping layer 170 and the upper insulating layer 180 are etched to form vias 200_1 and trenches 200_2.

Referring now to FIG. 15, moisture is reduced in or possibly eliminated from the upper insulating layer 180 through the grooves 200 which consist of the vias 200_1 and the trenches 200_2, respectively. The moisture reduction process may be performed under the same conditions as those in FIG. 12.

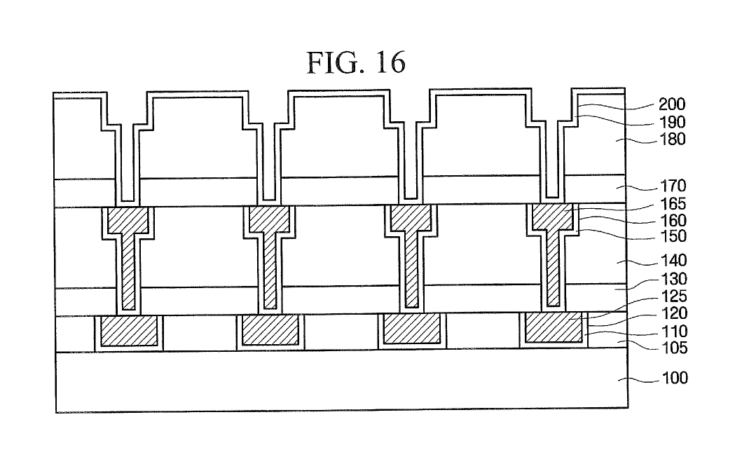

Referring now to FIG. 16, a barrier metal layer 190 is formed on the upper insulating layer 180 and inner sidewalls and a bottom surface of each of the grooves 200 by using the method described above with reference to FIG. 13. In these embodiments, the moisture reduction process of FIG. 15 and the process of forming the barrier metal layer 190 of FIG. 16 may be performed in situ. Accordingly, the possibility that moisture will seep into the upper insulating layer 180 again is reduced.

Referring now to FIG. 9, a conductive wiring 205 is formed in each of the grooves 200.

Referring now to FIGS. 10, 11, and 1, dummy vias 300 are formed, and the upper insulating layer 180 is heat-treated and vacuum-treated to reduce or possibly eliminate moisture from the upper insulating layer 180. A dummy via barrier metal layer 310 is formed to cover sidewalls and a bottom surface of each of the dummy vias 300. The moisture reduction process and the process of forming the dummy via barrier metal layer 310 may be performed in situ, so that moisture does not seep into the upper insulating layer 180 again is reduced.

As discussed above, moisture is reduces or possibly eliminated while the insulating layers 140 and 180 are formed. In addition, after the upper insulating layer 180 is formed, the dummy vias 300 are formed, and moisture is eliminated. Therefore, moisture can be more efficiently eliminated from the insulating layers 140 and 180.

Although illustrated in a separate drawing, the dummy vias 300 may be formed at the same time as the grooves 160 (which consist of the vias 160_1 and the trenches 160_2, respectively, in FIG. 6) in the present embodiment. In this case, moisture is eliminated through the grooves 160 and the dummy vias 300 in the heat-treatment and vacuum-treatment processes. Forming the conductive wiring 165 (see FIG. 14) comprises forming conductive metal materials in the dummy vias after forming dummy via barrier metal layers 150 in each of the dummy vias.

In these embodiments, each of the dummy vias 300 is also filled with the conductive metal material (see FIG. 3A).

Processing steps in the fabrication of semiconductor device according to some embodiments of the present invention will be discussed with respect to FIGS. 1, 4 through 11, 17, and 18. Through the processes described above with reference to FIGS. 4 through 8, a conductive metal material 165_3 is formed in each of grooves 160. The CMP process is performed on the conductive metal material 165_3 to form a conductive wring layer 165.

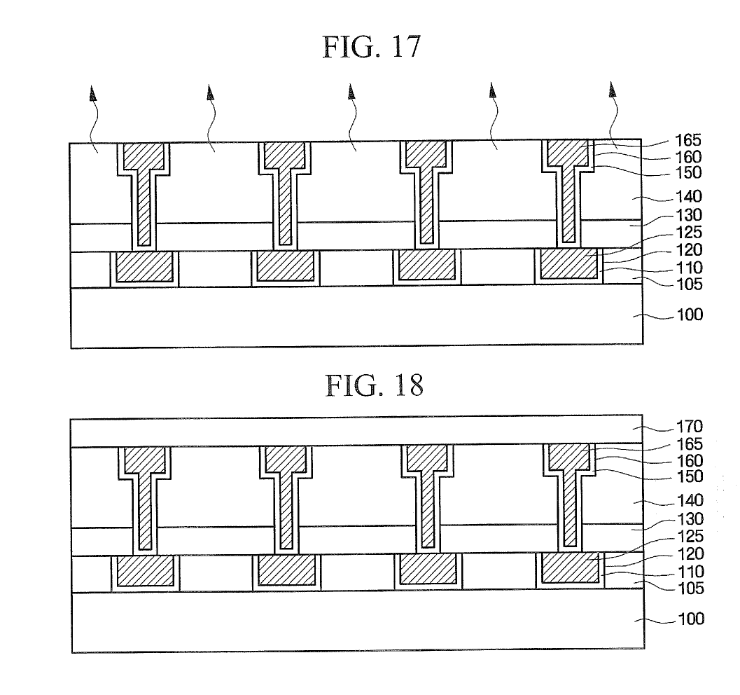

Referring now to FIG. 17, an insulating layer 140 is heat-treated and vacuum-treated to reduce or possibly eliminate moisture from the insulating layer 140. The moisture reduction process is performed at a temperature of from about 30 to about 400° C. and under a high-vacuum pressure of from about 0.1 to about 10 torr.

Referring now to FIG. 18, the insulating layer 140 having the moisture removed is covered with an upper capping layer 170 which reduces or possibly prevents moisture from seeping into the insulating layer 140 again.

The moisture reduction process of FIG. 17 and the process of forming the upper capping layer 170 may be performed in situ, so that moisture does not seep into the insulating layer 140 again between the two processes.

Referring now to FIGS. 9 through 11 and 1, an upper insulating layer 180 is formed on the upper capping layer 170, and a conductive wring layer 205 is formed in each of grooves 200. Then, dummy vias 300 are formed, and the upper insulating layer 180 is heat-treated and vacuum-treated to reduce or possibly eliminate moisture from the upper insulating layer 180. A dummy via barrier metal layer 310 is formed to cover sidewalls and a bottom surface of each of the dummy vias 300. The moisture reduction process and the process of forming the dummy via barrier metal layer 310 may be performed in situ, so that moisture does not seep into the upper insulating layer 180 again.

As discussed above, moisture is reduced or possibly eliminated while the insulating layers 140 and 180 are formed. In addition, after the upper insulating layer 180 is formed, the dummy vias 300 are formed, and moisture is eliminated. Therefore, moisture can be more efficiently eliminated from the insulating layers 140 and 180.

Although not illustrated in a separate drawing, the dummy vias 300 may be formed after the conductive wiring 165 is formed and before the upper capping layer 170 is formed in the present embodiment. The dummy via barrier metal layer 310 may be formed on the sidewalls and the bottom surface of each of the dummy vias 300, and the upper capping layer 170 may be formed. In these embodiments, at least part of each of the dummy vias 300 may be filled with a material of the upper capping layer 170 (see FIG. 3B). Furthermore, the remaining part of each of the dummy vias 300 may be filled with a material of the upper insulating layer 180 (see FIG. 3B).

While some embodiments of the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

1.-13. (canceled)

14. A method of fabricating a semiconductor device, the method comprising:
providing a substrate;
forming an insulating layer, which has pores, on the substrate;
forming a conductive wiring in the insulating layer and forming dummy vias, each of which penetrates at least part of the insulating layer, is adjacent to the conductive wiring, and has a space therein;
reducing moisture in the insulating layer; and
forming a dummy via barrier metal layer which covers sidewalls and a bottom surface of each of the dummy vias,
wherein the reducing the moisture and the forming of the dummy via barrier metal layer are performed in situ.

15. The method of claim 14, wherein the reducing the moisture is performed at a temperature of from about 30 to about 400° C. and under a high-vacuum pressure of from about 0.1 to about 10 torr.

16. The method of claim 14, further comprising:
forming a plurality of lower insulating layers between the insulating layer and the substrate; and
forming a plurality of lower conductive wirings in the lower insulating layers, respectively,
wherein the insulating layer is a uppermost insulating layer, and the dummy vias penetrate from the uppermost insulating layer to a lowest one of the lower insulating layers.

17. The method of claim 16, further comprising forming a plurality of capping layers, each between two adjacent ones of the lower insulating layers and between the uppermost insulating layer and one of the lower insulating layers which is adjacent to the uppermost insulating layer.

18. The method of claim 17, wherein each of the lower conductive wirings, excluding a lowest one thereof, is formed in a corresponding one of the lower insulating layers and the capping layer disposed under the corresponding one of the lower insulating layers, and the conductive wiring is formed between the uppermost insulating layer and the capping layer disposed under the uppermost insulating layer.

19. The method of claim 14, wherein the forming of the conductive wiring comprises:
forming grooves by etching the insulating layer;
forming a conductive metal material on the insulating layer and each of the grooves; and
performing a chemical mechanical planarization (CMP) process on the conductive metal material to form the conductive wiring in each of the grooves.

20. The method of claim 19, wherein the dummy vias are formed at the same time as the grooves or after the conductive wiring is formed.

21. The method of claim 20, wherein the dummy vias are formed at the same time as the grooves, and the forming of the conductive wiring comprises filling each of the dummy vias with the conductive metal material after forming the dummy via barrier metal layer.

22. The method of claim 20, further comprising forming an upper capping layer on the insulating layer after forming the dummy via barrier metal layer, wherein the dummy vias are formed after the conductive wiring is formed, and the forming of the upper capping layer comprises filling at least part of each of the dummy vias with a material of the upper capping layer.

23. The method of claim 22, further comprising forming an upper insulating layer on the upper capping layer, wherein the forming of the upper insulating layer comprises filling at least part of each of the dummy vias with a material of the upper insulating layer.

24. The method of claim 19, further comprising:
reducing moisture in the insulating layer after forming the grooves; and
forming a barrier metal layer which covers sidewalls and a bottom surface of each of the grooves,
wherein the reducing of the moisture and the forming of the barrier metal layer are performed in situ.

25. The method of claim 24, wherein the reducing the moisture is performed at a temperature of from about 30 to about 400° C. and under a high-vacuum pressure of from about 0.1 to about 10 torr.

26. The method of claim 19, further comprising:
reducing moisture in the insulating layer after the CMP process; and
forming the upper capping layer which covers the conductive wiring and the insulating layer,
wherein the reducing the moisture and the forming of the upper capping layer are performed in situ.

27. The method of claim 26, wherein reducing the moisture is performed at a temperature of from about 30 to about 400° C. and under a high-vacuum pressure of from about 0.1 to about 10 torr.

28. The method of claim 19, wherein the grooves and the conductive wiring are formed by a copper (Cu) damascene process.

29-35. (canceled)
